(19) United States
(12) Patent Application Publication
(10) Pub. No.: US 2024/0186477 A1
(43) Pub. Date: Jun. 6, 2024

(54) LIGHT-EMITTING BASEPLATE AND DISPLAY APPARATUS

(71) Applicants: Hefei BOE Ruisheng Technology Co., Ltd., Hefei, Anhui (CN); BOE Technology Group Co., Ltd., Beijing (CN)

(72) Inventors: Xinxiu ZHANG, Beijing (CN); Bin PANG, Beijing (CN); Huayu SANG, Beijing (CN); Xue ZHAO, Beijing (CN); Qiang JI, Beijing (CN); Xiaodong XIE, Beijing (CN)

(21) Appl. No.: 18/574,299

(22) PCT Filed: Feb. 28, 2022
(86) PCT No.: PCT/CN2022/078233

§ 371 Date: Dec. 26, 2023

(51) Int. Cl. H01L 33/62; H01L 25/075

(52) U.S. Cl. CPC H01L 33/62; H01L 25/0753

(57) ABSTRACT

The present disclosure provides a light-emitting baseplate and a display apparatus. The light-emitting baseplate includes a bonding region and a light-emitting region; the light-emitting baseplate includes a substrate, solder pads located on the substrate and in the light-emitting region, bonding pins located on the substrate and in the bonding region, and a first insulation layer located at a side of the bonding pins away from the substrate. The light-emitting region includes two layers of conductive structure, and the bonding region includes one layer of conductive structure. The first insulation layer is provided with first openings located in the bonding region, and an orthographic projection of each of the first openings on the substrate is within an orthographic projection of one of the bonding pins on the substrate. The display apparatus includes the light-emitting baseplate.

### TECHNICAL FIELD

The present disclosure relates to the field of display technologies, and in particular to a light-emitting baseplate and a display apparatus.

### BACKGROUND

Mini-LED is a new LED display technology derived from small-spacing LED, which is also called sub-millimeter light-emitting diode. Its grains have a size of 100 μm to 300 μm, namely, between conventional LED and Micro LED. Due to good display effect, lightness and thinness experience, high contrast and long service life and so on, it has obvious use tendency in the display field.

There is a problem of easy peeling-off of a film layer on a bonding region of the existing Mini-LED baseplates, affecting the yield of the products.

### SUMMARY

The present disclosure provides a light-emitting baseplate and a display apparatus.

According to a first aspect of embodiments of the present disclosure, there is provided a light-emitting baseplate, including a bonding region and a light-emitting region; the light-emitting baseplate includes:
a substrate;
solder pads, located on the substrate and in the light-emitting region, where the light-emitting region includes two layers of conductive structure; and
bonding pins located on the substrate and in the bonding region, where the bonding region includes one layer of conductive structure;
a first insulation layer, located at a side of the bonding pins away from the substrate, where the first insulation layer is provided with first openings located in the bonding region, and an orthographic projection of each of the first openings on the substrate is within an orthographic projection of one of the bonding pins on the substrate.

In an embodiment, the light-emitting baseplate further includes a flux layer partially located in the first openings, and the flux layer has a thickness greater than a thickness of a part of the first insulation layer in the bonding region.

In an embodiment, the first insulation layer includes an inorganic layer in the bonding region.

In an embodiment, the light-emitting baseplate further includes a conductive layer and a second conductive layer located at a side of the first conductive layer away from the substrate; the solder pads include a first conductive structure and the bonding pins include a second conductive structure; and

the first conductive structure is located in the second conductive layer and the second conductive structure is located in the second conductive layer.

In an embodiment, the light-emitting baseplate further includes a transition region between the bonding region and the light-emitting region, where the transition region is provided with a connection trace located in the first conductive layer, and the light-emitting region is provided with a signal trace connected with the connection trace; and

the second conductive layer includes a connection portion in the transition region, the connection portion is connected with the second conductive structure, and the connection portion is partially located at a side of the connection trace away from the substrate and is connected with the connection trace.

In an embodiment, the first insulation layer covers the transition region.

In an embodiment, the connection portion includes a tilted portion, which is tilted up from the bonding region toward the light-emitting region in a direction away from the substrate.

In an embodiment, the light-emitting baseplate further includes a second insulation layer between the first conductive layer and the second conductive layer, where the second insulation layer is provided with second openings located in the transition region, an orthographic projection of the second openings on the substrate is within an orthographic projection of the connection trace on the substrate, and the connection portion is connected with the connection trace through the second openings.

In an embodiment, the light-emitting baseplate further includes a second insulation layer between the first conductive layer and the second conductive layer, where the second insulation layer covers the bonding region.

In an embodiment, the light-emitting baseplate includes a first conductive layer and a second conductive layer located at a side of the first conductive layer away from the substrate; where the solder pads include a first conductive structure and the bonding pins include a second conductive structure;

the first conductive structure is located in the second conductive layer and the second conductive structure is located in the first conductive layer.

In an embodiment, the light-emitting baseplate further includes a transition region between the bonding region and the light-emitting region, where the transition region is provided with a connection trace located in the first conductive layer, and the light-emitting region is provided with a signal trace connected with the connection trace;

the connection trace is connected with the second conductive structure.

In an embodiment, the light-emitting baseplate further includes a second insulation layer between the first conductive layer and the second conductive layer, where an orthographic projection of the second insulation layer on the substrate is located in a region outside the bonding region.

In an embodiment, the bonding pins include a second conductive structure and second conductive structures of adjacent bonding pins are spaced apart.

In an embodiment, the bonding pins include second conductive structures, the light-emitting baseplate further includes signal traces located in the light-emitting region, one of the signal traces is connected to multiple of the bonding pins; and in the bonding pins connected with the one of the signal traces, third conductive structures of at least two adjacent bonding pins are mutually connected.

In an embodiment, the third conductive structures of the bonding pins connected to the one of the signal traces are all mutually connected.

According to a second aspect of embodiments of the present disclosure, there is provided a display apparatus, including the above light-emitting baseplate.

In the light-emitting baseplate and the display apparatus provided by the embodiments of the present disclosure, the bonding region includes one layer of conductive structure, that is, the solder pads of the bonding region only have one layer of conductive film layer without a conductive film layer below. Thus, when a conductive film layer is below the solder pads, separation of the solder pads from the conductive film layer below the solder pads due to poor adhesive force between the solder pads and the conductive film layer below the solder pads can be avoided. The first insulation layer is provided with first openings located in the bonding region, and the orthographic projection of each of the first openings on the substrate is within the orthographic projection of one of the bonding pins on the substrate. Hence, the first openings will not expose an insulation layer below the first insulation layer and in the bonding region. In this way, over-etching of a part of the insulation layer below the first insulation layer in the bonding region at the time of etching the conductive structure of the bonding region can be avoided, thus avoiding film layer separation of the insulation layer below the first insulation layer in the bonding region from the conductive structure in the bonding region due to a recess formed by the over-etching of the part of the insulation layer in the bonding region below the first insulation layer. It can be known that the light-emitting baseplate provided by the embodiments of the present disclosure can alleviate the problem of film layer separation, thus increasing the product yield of the light-emitting baseplates.

### BRIEF DESCRIPTION OF THE DRAWINGS

FIG. 1 is a top view of a light-emitting baseplate according to an exemplary embodiment of the present disclosure.

FIG. 2 is a structural schematic diagram illustrating a light-emitting baseplate according to an exemplary embodiment of the present disclosure.

FIG. 3 is a partial sectional view of the light-emitting baseplate taken along the line AA in FIG. 2.

FIG. 4 is a partial sectional view of the light-emitting baseplate taken along the line BB in FIG. 2.

FIG. 5 is a structural schematic diagram illustrating a light-emitting baseplate according to another exemplary embodiment of the present disclosure.

FIG. 6 is a structural schematic diagram illustrating a light-emitting baseplate according to yet another exemplary embodiment of the present disclosure.

FIG. 7 is a partial sectional view of the light-emitting baseplate taken along the line CC in FIG. 6.

FIG. 8 is a partial sectional view of the light-emitting baseplate taken along the line DD in FIG. 6.

FIG. 9 is a structural schematic diagram illustrating a light-emitting baseplate according to another exemplary embodiment of the present disclosure.

FIG. 10 is a partial sectional view of the light-emitting baseplate taken along the line MM in FIG. 9.

FIG. 11 is a partial sectional view of the light-emitting baseplate taken along the line NN in FIG. 9.

### DETAILED DESCRIPTION OF THE EMBODIMENTS

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

The terms used in the present disclosure are for the purpose of describing particular examples only, and are not intended to limit the present disclosure. Terms determined by “a”, “the” and “said” in their singular forms in the present disclosure and the appended claims are also intended to include plurality, unless clearly indicated otherwise in the context. It should also be understood that the term “and/or” as used herein refers to and includes any or all possible combinations of one or more of the associated listed items.

It should be understood that, although the terms “first,” “second,” “third,” and the like may be used in the present disclosure to describe various information, such information should not be limited to these terms. These terms are only used to distinguish one category of information from another. For example, without departing from the scope of the present disclosure, first information may be referred as second information; and similarly, the second information may also be referred as the first information. Depending on the context, the term “if” as used herein may be interpreted as “when” or “upon” or “in response to determining”.

The embodiments of the present disclosure provide a light-emitting baseplate and a display apparatus. The light-emitting baseplate and the display apparatus in the embodiments of the present disclosure are detailed in combination with the accompanying drawings. In a case of no conflict, the features of the following embodiments can be mutually supplemented or combined.

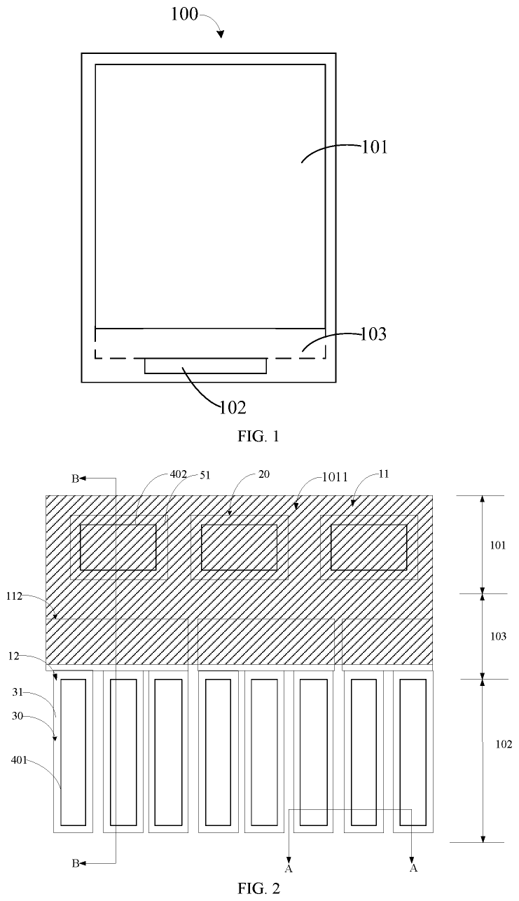

An embodiment of the present disclosure provides a light-emitting baseplate. As shown in FIG. 1, an embodiment of the present disclosure provides an array baseplate. As shown in FIG. 1, the array baseplate 100 includes a light-emitting region 101 and a bonding region 102. The bonding region 102 is disposed at a side of the light-emitting region 101. The bonding region 102 is provided with bonding pins bound to a FPC (Flexible Printed Circuit). The bonding pins are used for electrically connecting a drive chip of the light-emitting baseplate with the FPC. The light-emitting region 101 is provided with a plurality of solder pads used to solder light-emitting diodes.

The light-emitting baseplate provided by the embodiments of the present disclosure may be used as a display baseplate and may be further used as a backlight unit applied to a display apparatus. When the light-emitting baseplate is used as a backlight unit, the light-emitting region may be provided with a plurality of light-emitting zones, and each light-emitting zone is provided with a plurality of light-emitting diodes. The plurality of light-emitting diodes in each light-emitting zone may be series-connected. The light-emitting baseplate may be controlled based on zones. When the light-emitting baseplate is used as a display baseplate, each light-emitting diode is used as one sub-pixel.

In an embodiment, as shown in FIG. 1, the light-emitting baseplate further includes a transition region 103 between the light-emitting region 101 and the bonding region 102. The transition region 103 may be provided with a light-emitting diode or not provided with a light-emitting diode.

In an embodiment, as shown in FIGS. 2 to 4, the light-emitting baseplate includes a substrate 10, solder pads 20 on the substrate, bonding pins 30 on the substrate 10, and a first insulation layer 40 at a side of the bonding pins 30 away from the substrate 10. The solder pads 20 are located in the light-emitting region 101, and the bonding pins 30 are located in the bonding region 102. The light-emitting region 101 includes two layers of conductive structure, and the bonding region 102 includes one layer of conductive structure. The first insulation layer 40 is provided with a plurality of first openings 401 located in the bonding region 102, and an orthographic projection of each of the first openings 401 on the substrate 10 is within an orthographic projection of one of the bonding pins 30 on the substrate 10. The first openings 401 are in one-to-one correspondence with the bonding pins 30 respectively. The orthographic projection of each first opening 401 on the substrate 10 is within the orthographic projection of the corresponding bonding pin 30 on the substrate 10.

In the light-emitting baseplate provided by the embodiments of the present disclosure, the bonding region 102 includes one layer of conductive structure, namely, the solder pads 20 of the bonding region 102 only include one layer of conductive film layer without a conductive film layer below. Thus, when the conductive film layer is below the solder pads, separation of the solder pads from the conductive film layer below the solder pads due to poor adhesive force between the solder pads and the conductive film layer below the solder pads can be avoided. The first insulation layer 40 is provided with a plurality of first openings 401 located in the bonding region 102, and an orthographic projection of each of the first openings 401 on the substrate 10 is within an orthographic projection of one of the bonding pins 30 on the substrate 10. Hence, the first openings 401 will not expose an insulation layer below the first insulation layer 40 and in the bonding region. In this way, over-etching of a part of the insulation layer below the first insulation layer in the bonding region at the time of etching the conductive structure of the bonding region can be avoided, thus avoiding film layer separation of the insulation layer below the first insulation layer in the bonding region from the conductive structure in the bonding region due to a recess formed by the over-etching of the part of the insulation layer in the bonding region below the first insulation layer. It can be known that the light-emitting baseplate provided by the embodiments of the present disclosure can alleviate the problem of film layer separation, thus increasing the product yield of the light-emitting baseplates. Since there is no other conductive film layer below the conductive structure of the bonding region 102, the part of the insulation layer below the bonding pins in the bonding region 102 does not need to climb, and can be disposed to be thinner, helping with saving the costs of the light-emitting baseplate.

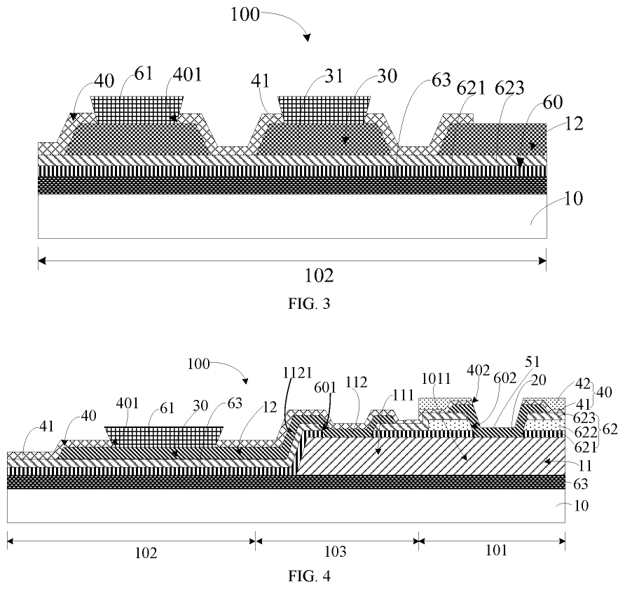

In an embodiment, as shown in FIGS. 2 and 3, the light-emitting baseplate 100 includes a first conductive layer 11 and a second conductive layer 12 located at a side of the first conductive layer 11 away from the substrate 10. At least a part of the first conductive layer 11 and the second conductive layer 12 is located in the light-emitting region 101. In the two layers of conductive structure of the light-emitting region 101, one layer of conductive structure is located in the first conductive layer 11 and the other layer of conductive structure is located in the second conductive layer 12. The conductive structure being located in the first conductive layer refers to that the conductive structure is a part of the first conductive layer; the conductive structure being located in the second conductive layer refers to that the conductive structure is a part of the second conductive layer.

The first conductive layer 11 in the light-emitting region 101 is generally used to arrange a plurality of signal traces 1011 including a public voltage signal trace, a drive voltage signal trace, a power supply signal trace and an address selection signal trace and the like. Optionally, the first conductive layer 11 has a thickness of 1.5 μm to 7 μm and can be made from a material including copper, for example, by sputter, for example, a laminated material of MoNb/Cu/MoNb. The bottom layer MoNb is used to increase an adhesive force, the middle layer Cu is used to transfer electrical signals and the top layer MoNb is used to prevent oxidation. The first conductive layer 11 may also be formed by electroplating: a seed layer MoNiTi is firstly formed to increase a grain nucleation density, and an anti-oxidation layer MoNiTi is prepared after electroplating.

The second conductive layer 12 in the light-emitting region 101 is used to arrange solder pads 20 and a wire for connection. The solder pads 20 are used to mount light-emitting diodes and the wire can be a wire for series-connecting a plurality of light-emitting diodes in a same light-emitting unit. Optionally, the second conductive layer 12 has a thickness of about 6000 Å, and can be made from a material such as a laminated material of MoNb/Cu/MoNb, where the bottom layer MoNb is used to increase an adhesive force, the middle layer Cu is used to transfer electrical signals and the top layer MoNb is used to prevent oxidation.

In an embodiment, as shown in FIGS. 3 and 4, the light-emitting baseplate 100 further includes a flux layer 61 partially located in the first openings 401. The flux layer 61 has a thickness greater than a thickness of a part of the first insulation layer 40 in the bonding region 102. When the bonding pins are bound to the FPC, the bonding pins and solder on the FPC may consume the conductive material of the bonding pins during soldering. If poor soldering between the bonding pins and the FPC occurs, secondary soldering is required. At this time, if the conductive material of the bonding pins is mostly or all consumed, secondary soldering cannot be performed. The flux layer 61 can be used to bond the bonding pins to the FPC during secondary soldering so as to solve the problem of inability to perform secondary soldering using the solder pad, thereby increasing the product yield. Furthermore, since the bonding region 102 includes one layer of conductive structure and there is no other conductive film layer below the conductive structure of the bonding region 102, there will be no problem of separation of the conductive structure of the bonding region 102 from the conductive film layer below the conductive structure due to a stress generated by the flux layer 61. Therefore, the product yield of the light-emitting baseplates is increased. Furthermore, since there is no other conductive film layer below the conductive structure of the bonding region 102, the size of the bonding pins of the bonding region is free from the influence of the aligning deviation of other conductive film layers at the time of manufacturing the conductive structure of the bonding region. An area of the bonding pins may be disposed to be larger to help reduce a resistance of signal traces connected with the bonding pins, and reduce the voltage drop and the generated heat of the signal traces of the light-emitting baseplate.

In an embodiment, the flux layer 61 has a thickness of 3.03 μm to 5.1 μm. In this case, the following problems can be avoided: due to large thickness of the flux layer 61, the flux layer 61 cannot effectively solve the problem of inability to perform secondary soldering using the solder pad, the thickness of the flux layer 61 is large and the preparation time is long.

In an embodiment, the process of forming the flux layer 61 is as follows: firstly, an electroless nickel process is used to form a nickel layer having a thickness of 3 μm to 5 μm; then, an electroless gold process is used to form a gold layer having a thickness of 0.03 μm to 0.1 μm on the nickel layer. Before the nickel layer is formed, the MoNb material on the top of the second conductive layer 12 may be etched off firstly to expose Cu below so as to prevent the influence of the MoNb material on top on growth of the nickel layer and the gold layer. In the embodiments of the present disclosure, by enabling the orthographic projection of each first opening 401 on the substrate 10 to be within the orthographic projection of one of the bonding pins 30 on the substrate 10, separation of the insulation layer below the first insulation layer 40 from the second conductive layer 12 due to a recess formed by the over-etching of the part of the insulation layer in the bonding region below the first insulation layer 40 at the time of etching the MoNb material on the top of the second conductive layer 12 can be avoided, thereby helping increase the product yield of the light-emitting baseplate.

In an embodiment, the first insulation layer 40 includes an inorganic layer 41 located in the bonding region 102. In this case, the inorganic layer can block water vapor to reduce the amount of water vapor entering the bonding pins 30, thus helping increase the reliability of the light-emitting baseplate. The material of the inorganic layer 41 may be, for example, silicon oxide or silicon nitride.

In some embodiments, a part of the first insulation layer 40 in the bonding region 102 may only include the inorganic layer.

In an embodiment, the part of the first insulation layer 40 in the light-emitting region 101 is provided with third openings 402, and an orthographic projection of each of the third openings 402 on the substrate 10 is within an orthographic projection of one solder pad 20 on the substrate 10. The third openings 402 in one-to-one correspondence with the solder pads 20 respectively. The orthographic projection of each of the third openings 402 on the substrate 10 is within the orthographic projection of the corresponding solder pad 20 on the substrate 10.

In some embodiments, the part of the first insulation layer 40 in the light-emitting region 101 may include the inorganic layer 41 and a first organic layer 42 located at a side of the inorganic layer 41 away from the substrate 10. The first organic layer may be made from an organic resin.

In an embodiment, the solder pads 20 may include a first conductive structure 51 and the bonding pins 30 include a second conductive structure 31. The first conductive structure 51 is located in the second conductive layer 12 and the second conductive structure 31 is located in the second conductive layer 12. That is, the first conductive layer 11 is not disposed in the bonding region 102. In this case, a time interval between a time of forming the bonding pins 30 and a time of forming the first insulation layer 40 is made small to help prevent the middle layer Cu of the bonding pins 30 from being oxidized severely and ensure the bonding effectiveness of the bonding pins 30 and FPC.

In an embodiment, as shown in FIG. 4, the transition region 103 is provided with a connection trace 111 located in the first conductive layer 11, and the light-emitting region 101 is provided with a signal trace 1011 connected with the connection trace 111. The second conductive layer 12 includes a connection portion (or lapping portion) 112 located in the transition region 103. The connection portion 112 is connected with the second conductive structure 31, and partially located at a side of the connection trace 111 away from the substrate 10 and connected with the connection trace 111. In this disposal, the signal trace 1011 of the light-emitting region 101 can be electrically connected to the bonding pins 30 through the connection trace 111 and the connection portion 112.

In an embodiment, as shown in FIG. 4, the connection portion 112 has a tilted portion 1121 which is tilted up from the bonding region 102 to the light-emitting region 101 in the direction away from the substrate 10. Enabling the tilted portion 1121 to be tilted up from the bonding region 102 to the light-emitting region 101 helps to avoid breakage of the connection portion 112 during a climbing process.

In an embodiment, the first insulation layer 40 covers the transition region 103. In this disposal, the first insulation layer 40 can block water vapor to effectively reduce the amount of water vapor entering the connection portion 112 and the connection trace 111, thus helping increase the reliability of the light-emitting baseplate.

In an embodiment, the part of the first insulation layer 40 in the transition region 103 may only include the inorganic layer 41, and the orthographic projection of the first organic layer 42 on the substrate 10 is located in a region outside the transition region 103.

In an embodiment, as shown in FIGS. 3 and 4, the light-emitting baseplate 100 further includes a second insulation layer 62 between the first conductive layer 11 and the conductive layer 12.

In an embodiment, the second insulation layer 62 may include a single film layer or a plurality of film layers. For example, as shown in FIGS. 3 and 4, the second insulation layer 62 includes a first inorganic layer 621, a second organic layer 622 located at a side of the first inorganic layer 621 away from the substrate 10, and a second inorganic layer 623 located at a side of the second organic layer 622 away from the substrate 10.

In an embodiment, the second insulation layer 62 covers the bonding region 102. In this disposal, it is not required to etch the part of the second insulation layer 62 in the bonding region 102 so as to prevent damage to the substrate 10 during etching of the second insulation layer 62. The second insulation layer 62 can also protect the substrate 10 to prevent damage to the substrate 10 during etching of the film layer above the substrate 10.

In an embodiment, the part of the second insulation layer 62 in the bonding region 102 includes the first inorganic layer 621 and the second inorganic layer 623, that is, an orthographic projection of the second organic layer 622 on the substrate 10 is located in a region outside the bonding region 102. The part of the second organic layer 622 in the bonding region 102 is etched off.

In an embodiment, the second insulation layer 62 is provided with second openings 601 located in the transition region 103. An orthographic projection of the second openings 601 on the substrate 10 is within an orthographic projection of the connection trace 111 on the substrate 10. The connection portion 112 is connected with the connection trace 111 through the second openings 601. In this case, the second insulation layer 62 can block water vapor to effectively reduce the amount of water vapor entering the connection portion and the connection trace, helping increase the reliability of the light-emitting baseplate. Further, the disposal of the second openings 601 in the second insulation layer 62 does not affect the connection between the connection portion 112 and the connection trace 111.

In an embodiment, the part of the second insulation layer 62 in the transition region 103 includes the first inorganic layer 621 and the second inorganic layer 623, that is, the orthographic projection of the second organic layer 622 on the substrate 10 is located in a region outside the transition region 103 and the part of the second organic layer 622 in the transition region 103 is etched off. The second openings 601 penetrate through the first inorganic layer 621 and the second inorganic layer 623.

In an embodiment, the second insulation layer 62 is provided with a plurality of fourth openings 602 located in the light-emitting region 101. An orthographic projection of each of the fourth openings 602 on the substrate 10 is within the orthographic projection of one solder pad 20 on the substrate 10. The fourth openings 602 are in one-to-one correspondence with the solder pads 20 respectively. The orthographic projection of each of the fourth openings 602 on the substrate 10 is within the orthographic projection of the corresponding solder pad 20 on the substrate 10. The solder pads 20 are electrically connected to the part of the first conductive layer 11 in the light-emitting region 11 through the fourth openings 602.

In an embodiment, the part of the second insulation layer 62 in the light-emitting region 101 includes the first inorganic layer 621, the second organic layer 622 and the second inorganic layer 623. The fourth openings 602 penetrate through the first inorganic layer 621, the second organic layer 622 and the second inorganic layer 623.

In an embodiment, the array baseplate further includes a passivation protection layer 63 located at a side of the substrate 10 facing toward the first conductive layer 11. The passivation protection layer 63 can be in direct contact with the substrate 10. The passivation protection layer 63 can protect the substrate 10 to prevent damage to the substrate 10 during etching of the film layer above the substrate 10. The material of the passivation protection layer 63 may be an inorganic material, such as silicon oxide or silicon nitride.

In an embodiment as shown in FIGS. 2 and 3, the second conductive structures 31 of adjacent bonding pins 30 are spaced apart. A plurality of bonding pins 30 may be connected to a same connection portion 112 or each bonding pin 30 may be connected to one connection portion 112.

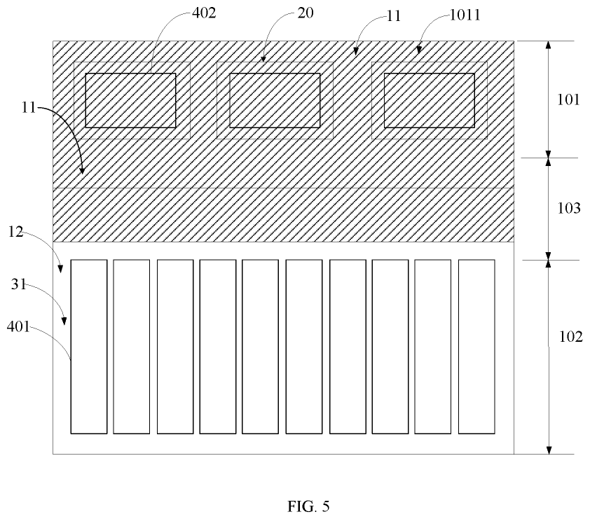

In another embodiment, as shown in FIG. 5, the light-emitting baseplate may further include a plurality of signal traces 1011 located in the light-emitting region 101, and a same signal trace 1011 is connected to a plurality of bonding pins 30. In the plurality of bonding pins 30 connected to the same signal trace 1011, the second conductive structures 31 of at least two adjacent bonding pins 30 are connected. The connection of the second conductive structures 31 of adjacent bonding pins 30 may refer to that no gap is provided between the second conductive structures 31 of two adjacent bonding pins 30. When the second conductive structure 31 of the bonding pins 30 are formed, an area of the second conductive structures 31 is free from influence of the aligning deviation of the first openings, and there is no need to dispose a gap between adjacent bonding pins. In this way, the area of the bonding pins can be disposed to larger to help reduce a resistance of the signal traces 1011 connected with the bonding pins 30, and reduce the voltage drop and the generated heat of the signal traces of the light-emitting baseplate.

In an embodiment, third conductive structures 31 of the bonding pins 30 connected to one of the signal traces 1011 are connected. In this case, the area of the third conductive structures 31 of the bonding pins 30 connected to one of the signal traces 1011 can be disposed to be larger to further reduce the resistance of the signal traces 1011 connected to the bonding pins 30 and reduce the voltage drop and the generated heat of the signal traces of the light-emitting baseplate.

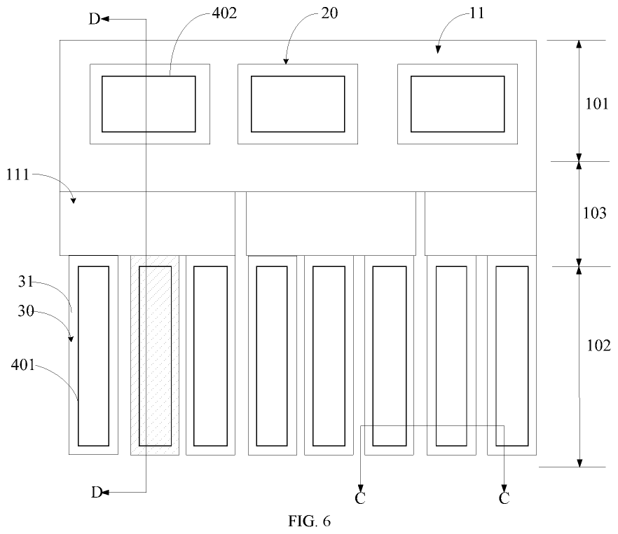

An embodiment of the present disclosure further provides another display baseplate. In this embodiment, the light-emitting baseplate may be as shown in FIGS. 6 to 8. The following descriptions are only made to the differences between the display baseplate shown in FIGS. 6 to 8 and the light-emitting baseplate shown in FIGS. 2 to 5, with same parts omitted.

In this embodiment, as shown in FIGS. 6 to 8, the second conductive structures 31 are located in the first conductive layer 11. After the first conductive layer 11 is formed, a protective layer covering the second conductive structures 31 may be first formed to prevent the second conductive structures 31 from being oxidized during a forming process of a film layer above the first conductive layer 11. Before the first insulation layer 40 is formed, the protective layer is removed. The material of the protective layer may be an inorganic material to better avoid oxidation of the second conductive structures 31.

In an embodiment, as shown in FIGS. 6 and 8, the transition region 103 is provided with a connection trace 111 located in the first conductive layer 11 and the light-emitting region 101 is provided with signal traces 1011 connected with the connection trace 111. The connection trace 111 is connected with the second conductive structure 31. In this disposal, the connection trace 111 and the second conductive structures 31 are located in a same layer and can be directly connected without using an connection portion, thereby simplifying the structural complexity of the light-emitting structure.

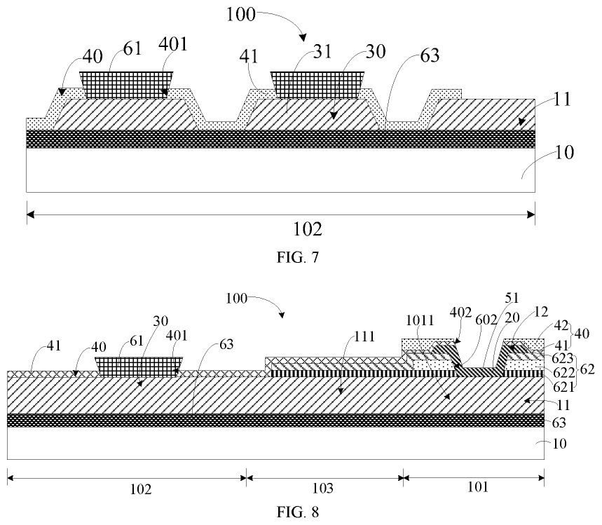

In an embodiment, as shown in FIGS. 7 and 8, an orthographic projection of the second insulation layer 62 on the substrate 10 is located in a region outside the bonding region 102. The second conductive structures 31 will not be covered by the second insulation layer 62 such that the second conductive structures 31 can be exposed through the first openings 401. Further, the bonding region 102 is not provided with the second insulation layer 62 and thus the second insulation layer 62 does not need to climb in the bonding region. The thickness of the second insulation layer 62 can be disposed to be smaller to reduce the costs of the light-emitting baseplate.

In an embodiment as shown in FIG. 8, the second insulation layer 62 covers the transition region 103. Thus, the part of the second insulation layer 62 in the transition region 103 can block water vapor from further entering the connection trace 111 of the transition region 103, thereby increasing the reliability of the light-emitting baseplate.

An embodiment of the present disclosure further provides a manufacturing method of a light-emitting baseplate. The manufacturing method of the light-emitting baseplate is described below. In this embodiment, descriptions are made only with the light-emitting baseplate shown in FIGS. 2 to 4 as example. The “patterning processes” described in the embodiment of the present disclosure includes film layer deposition, photoresist coating, mask exposure, developing, etching and photoresist stripping and the like. The deposition may be one or more of self sputtering, evaporation and chemical vapor deposition, and the etching may be one or more of dry etching and wet etching. The “film” refers to one layer of film prepared on a substrate by using a material based on deposition or coating process. If no patterning process is required for the “film” during the entire preparation process, the “film” may also be referred to as “layer”. If a patterning process is required for the “film” during the entire preparation process, the “film” before the patterning process is referred to as “film” and after the patterning process, is referred to as “layer”. The “layer” after the patterning process includes at least one “pattern”.

The method of preparing the light-emitting baseplate includes the following steps.

Firstly, a substrate 10 is provided.

Next, a passivation protection layer 63 is deposited on the substrate.

Next, a first conductive film is deposited on the passivation protection layer 63, patterning is performed on the first conductive film through a patterning process to obtain a first conductive layer 11, and signal traces 1011 in a light-emitting region 101 and a connection trace 111 in a transition region 103 are obtained.

Next, a first inorganic film is deposited.

Next, a second organic film is deposited, patterning is performed on the second organic film through a patterning process to obtain a second organic layer 622, where the second organic layer 622 is located in the light-emitting region 101 and is provided with first sub-openings located in the light-emitting region 101.

Next, a second inorganic film is deposited, and patterning is performed on the first inorganic film and the second inorganic film by using a same mask at the same time to obtain a first inorganic layer 621 and a second inorganic layer 623, where the first inorganic layer 621 and the second inorganic layer 623 are located in the light-emitting region 101, a bonding region 102 and the transition region 103, and the first inorganic layer 621 and the second inorganic layer 623 are provided with second openings 601 located in the transition region 103 and second sub-openings located in the light-emitting region 101; each first sub-opening corresponds to one second sub-opening, so as to form a fourth opening 602.

Next, a second conductive film is deposited, and patterning is performed on the second conductive film by using a patterning process to obtain a second conductive layer 12. Solder pads 20 in the light-emitting region 101, bonding pins 30 in the bonding region 102 and connection portion 112 in the transition region 103 are formed.

Next, a second inorganic film is deposited and patterning is performed on the second inorganic film by using a patterning process to obtain an inorganic layer 41 located in the light-emitting region 101, the bonding region 102 and the transition region 103. The inorganic layer 41 is provided with third sub-openings in the light-emitting region 101 and first openings 401 in the bonding region 102.

Next, a first organic film is deposited and patterning is performed on the first organic film by using a patterning process to obtain a first organic layer 42 which is located in the light-emitting region 101. The first organic layer 42 is provided with fourth sub-openings in the light-emitting region 101; and each third sub-opening corresponds to one fourth sub-opening to form a third opening 402.

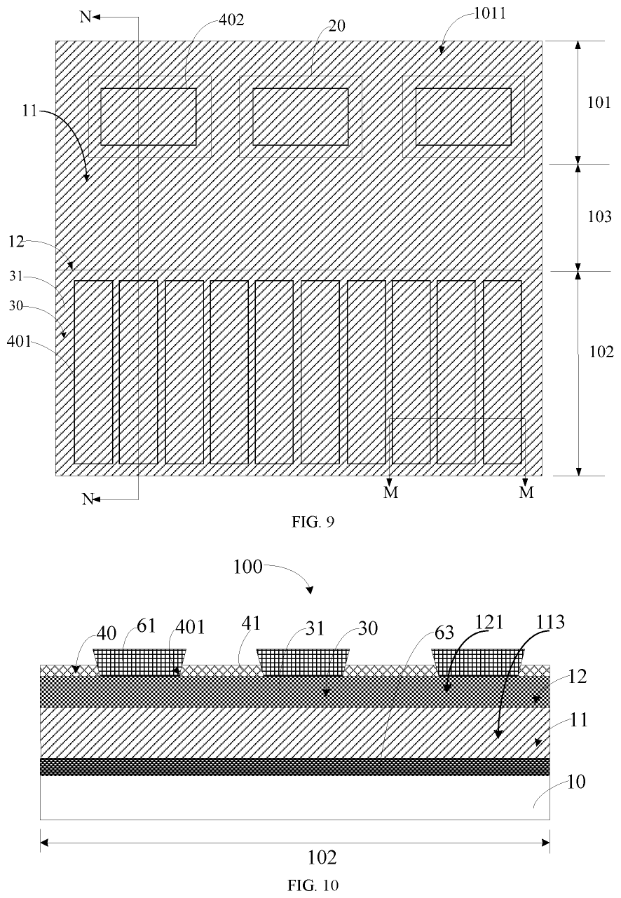

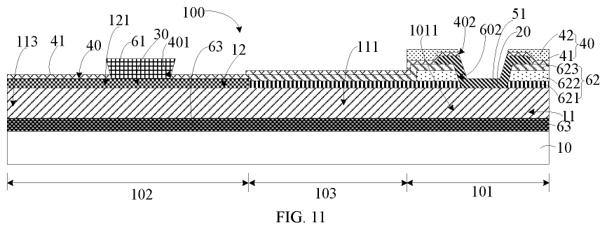

An embodiment of the present disclosure further provides another light-emitting baseplate. In this embodiment, the light-emitting baseplate may be as shown in FIGS. 9 to 11. The following descriptions are only made to the differences between the display baseplate shown in FIGS. 9 to 11 and the light-emitting baseplate shown in FIGS. 2 to 5, with same parts omitted.

As shown in FIGS. 9 to 11, the bonding region 102 of the light-emitting baseplate 100 includes two layers of conductive structure which respectively include a part of the first conductive layer 11 in the bonding region 102 and a part of the second conductive layer 12 in the bonding region 102. The second conductive structures 31 of the bonding pins 30 are located in the second conductive layer 12. One of the signal traces 1011 is connected to multiple of the bonding pins 30; and in the bonding pins 30 connected with the one of the signal traces 1011, the second conductive structures 31 of at least two adjacent bonding pins 30 are mutually connected. The connection of the second conductive structures 31 of adjacent bonding pins 30 may refer to that no gap is provided between the second conductive structures 31 of two adjacent bonding pins 30. In this disposal, an area of the bonding pins 30 can be increased such that an area of a part of the second conductive layer 12 in the bonding region 102, which is in contact with the first conductive layer 11, is increased, so as to improve an adhesive force of the first conductive layer 11 and the second conductive layer 12, and mitigate the problem of easy separation of the second conductive structures 31 of the bonding pins 30 and the second conductive layer 12; further, the increased area of the bonding pins 30 helps to reduce the resistance of the signal traces 1011 connected with the bonding pins 30 and reduce the voltage drop and the generated heat of the signal traces of the light-emitting baseplate.

In an embodiment, third conductive structures 31 of the bonding pins 30 connected to the one of the signal traces 1011 are connected. In this case, the area of the third conductive structures 31 of the bonding pins 30 connected to one of the signal traces 1011 can be disposed to be larger to further increase an adhesive force between the part of the second conductive layer 12 in the bonding region 102 and the first conductive layer 11 and further reduce the resistance of the signal traces 1011 connected to the bonding pins 30 and reduce the voltage drop and the generated heat of the signal traces of the light-emitting baseplate.

In an embodiment, the second conductive structures 31 of the bonding pins 30 connected to one of the signal traces 1011 are connected to form second sub-conductive portions 121, and the part of the first conductive layer 11 in the bonding region 102 includes a plurality of first sub-conductive portions 113. An orthographic projection of each first sub-conductive portion 113 on the substrate 10 is substantially in coincidence with an orthographic projection of one second sub-conductive portion 121 on the substrate 10. In this way, the part of the first conductive layer 11 in the bonding region 102 will not result in signal interference to adjacent signal traces 1011.

In an embodiment, the orthographic projection of the second insulation layer 62 on the substrate 10 is located outside the bonding region 102, that is, the part of the second insulation layer 62 in the bonding region 102 is etched off. In this case, the second insulation layer 62 does not need to climb in the bonding region 102 so as to reduce the thickness of the second insulation layer 62 and lower the costs of the light-emitting baseplate.

In an embodiment, the transition region 103 is provided with a connection trace 111 located in the first conductive layer 11, and the light-emitting region 101 is provided with signal traces 1011 connected with the connection trace 111. The connection trace 111 is connected with the first sub-conductive portions 113. In this disposal, the connection trace 111 and the first sub-conductive portions 113 are located in a same layer and can be directly connected without using an connection portion, thereby simplifying the structural complexity of the light-emitting structure.

In an embodiment, the second insulation layer 62 covers the transition region 103. In this disposal, the second insulation layer 62 helps to block water vapor from penetrating into the connection trace 111, so as to increase the reliability of the light-emitting baseplate.

An embodiment of the present disclosure provides a manufacturing method of a light-emitting baseplate for manufacturing the light-emitting baseplate shown in FIGS. 9 to 11. The manufacturing method of the light-emitting baseplate includes the following steps.

Firstly, a substrate 10 is provided.

Next, a passivation protection layer 63 is deposited on the substrate 10.

Next, a first conductive film is deposited on the passivation protection layer 63, and patterning is performed on the first conductive film through a patterning process to obtain a first conductive layer 11. Signal traces 1011 in a light-emitting region 101, first sub-conductive portions 113 in a bonding region 102, and a connection trace 111 in a transition region 103 are obtained.

Next, a first inorganic film is deposited.

Next, a second organic film is deposited, patterning is performed on the second organic film through a patterning process to obtain a second organic layer 622 which is located in the light-emitting region 101, and the second organic layer 622 is provided with first through openings located in the light-emitting region 101.

Next, a second inorganic film is deposited, and patterning is performed on the first inorganic film and the second inorganic film by using a same mask at the same time to obtain a first inorganic layer 621 and a second inorganic layer 623; the first inorganic layer 621 and the second inorganic layer 623 are located in the transition region 103 and the light-emitting region 101, second through openings are formed in the first inorganic layer 621 and the second inorganic layer 623, and the second through openings correspond to the first through openings to form fourth openings 602.

Next, a second conductive film is deposited, patterning is performed on the second conductive film through a patterning process to obtain a second conductive layer 12, and solder pads 20 in the light-emitting region 101 and bonding pins 30 in the bonding region 102 are obtained.

Next, a second inorganic film is deposited, patterning is performed on the second inorganic film through a patterning process to obtain an inorganic layer 41 which is located in the light-emitting region 101, the bonding region 102 and the transition region 103, and the inorganic layer 41 is provided with third through openings in the light-emitting region 101 and first openings 401 in the bonding region 102.

Next, a first organic film is deposited, patterning is performed on the first organic film through a patterning process to obtain a first organic layer 42 which is located in the light-emitting region 101, the first organic layer 42 is provided with fourth through openings in the light-emitting region 101, and the third through openings and the fourth through openings form third openings 402.

An embodiment of the present disclosure further provides a display apparatus including the light-emitting baseplate according to any one of the above embodiments. Since the display apparatus includes the above light-emitting baseplate, it has the same beneficial effects which will not be repeated herein.

In some embodiments, the display apparatus may be a liquid crystal display apparatus including a liquid crystal panel and a backlight source disposed at a non-display side of the liquid crystal panel. The backlight source includes the light-emitting baseplate described in any one of the above embodiments. The liquid crystal display apparatus can have more uniform backlight brightness and better display contrast.

In another embodiment, the array baseplate in the display apparatus is used as display baseplate. When the light-emitting baseplate is used as display baseplate, each inorganic light-emitting diode serves as one sub-pixel.

In the present disclosure, the application of the display apparatus is not limited. The display apparatus may be a television, a laptop computer, a tablet computer, a wearable display device, a smart phone, a vehicle-mounted display, a navigation device, an electronic book, a digital photo frame, an advertising light box and other products or components which have display function.

It should be noted that in the accompanying drawings, for illustration clarity, the sizes of the layers and regions may be exaggerated. Furthermore, it may be understood that when an element or a layer is referred to as being “on” another element or another layer, the element or the layer may be directly on another element or another layer or there is an intermediate layer therebetween. Further, it may be understood that when an element or layer is referred to as being “under” another element or another layer, the element or the layer may be directly under another element or another layer, or one or more intermediate elements or layers are present therebetween. In addition, it may also be understood that when a layer or element is referred to as being between two layers or elements, such layer or element may be a sole layer between the two layers or elements, or one or more intermediate layers or elements are present. Like reference signs in the descriptions indicate like elements.

Other implementations of the present disclosure will be apparent to those skilled in the art from consideration of the specification and practice of the present disclosure herein. The present disclosure is intended to cover any variations, uses, modification or adaptations of the present disclosure that follow the general principles thereof and include common knowledge or conventional technical means in the related art that are not disclosed in the present disclosure. The specification and examples are considered as exemplary only, with a true scope and spirit of the present disclosure being indicated by the following claims.

It should be understood that the present disclosure is not limited to the precise structure described above and shown in the accompanying drawings, and that various modifications and changes may be made without departing from the scope thereof. The scope of the present disclosure is limited only by the appended claims.

1. A light-emitting baseplate, comprising a bonding region and a light-emitting region, wherein the light-emitting baseplate comprises:
a substrate;
solder pads, located on the substrate and in the light-emitting region, wherein the light-emitting region comprises two layers of conductive structure;
bonding pins, located on the substrate and in the bonding region, wherein the bonding region comprises one layer of conductive structure; and
a first insulation layer, located at a side of the bonding pins away from the substrate, wherein the first insulation layer is provided with first openings located in the bonding region, and an orthographic projection of each of the first openings on the substrate is within an orthographic projection of one of the bonding pins on the substrate.

2. The light-emitting baseplate according to claim 1, further comprising: a flux layer partially located in the first openings, and the flux layer has a thickness greater than a thickness of a part of the first insulation layer in the bonding region.

3. The light-emitting baseplate according to claim 1, wherein the first insulation layer comprises an inorganic layer located in the bonding region.

4. The light-emitting baseplate according to claim 1, comprising: a first conductive layer and a second conductive layer located at a side of the first conductive layer away from the substrate; wherein the solder pads comprise a first conductive structure and the bonding pins comprise a second conductive structure; and
the first conductive structure is located in the second conductive layer and the second conductive structure is located in the second conductive layer.

5. The light-emitting baseplate according to claim 4, further comprising: a transition region between the bonding region and the light-emitting region, wherein the transition region is provided with a connection trace located in the first conductive layer, and the light-emitting region is provided with a signal trace connected with the connection trace; and
the second conductive layer comprises a connection portion located in the transition region, the connection portion is connected with the second conductive structure, and the connection portion is partially located at a side of the connection trace away from the substrate and is connected with the connection trace.

6. The light-emitting baseplate according to claim 5, wherein the first insulation layer covers the transition region.

7. The light-emitting baseplate according to claim 5, wherein the connection portion comprises a tilted portion which is tilted up from the bonding region toward the light-emitting region in a direction away from the substrate.

8. The light-emitting baseplate according to claim 5, further comprising: a second insulation layer between the first conductive layer and the second conductive layer, wherein the second insulation layer is provided with second openings located in the transition region, an orthographic projection of the second openings on the substrate is within an orthographic projection of the connection trace on the substrate, and the connection portion is connected with the connection trace through the second openings.

9. The light-emitting baseplate according to claim 5, further comprising: a second insulation layer between the first conductive layer and the second conductive layer, wherein the second insulation layer covers the bonding region.

10. The light-emitting baseplate according to claim 1, further comprising: a first conductive layer and a second conductive layer located at a side of the first conductive layer away from the substrate; wherein the solder pads comprise a first conductive structure and the bonding pins comprise a second conductive structure;
the first conductive structure is located in the second conductive layer and the second conductive structure is located in the first conductive layer.

11. The light-emitting baseplate according to claim 10, further comprising: a transition region between the bonding region and the light-emitting region, wherein the transition region is provided with a connection trace located in the first conductive layer, and the light-emitting region is provided with a signal trace connected with the connection trace;
the connection trace is connected with the second conductive structure.

12. The light-emitting baseplate according to claim 11, further comprising: a second insulation layer between the first conductive layer and the second conductive layer, wherein an orthographic projection of the second insulation layer on the substrate is located in a region outside the bonding region.

13. The light-emitting baseplate according to claim 1, wherein the bonding pins comprise a second conductive structure and second conductive structures of adjacent bonding pins are spaced apart.

14. The light-emitting baseplate according to claim 1, wherein the bonding pins comprise second conductive structures, the light-emitting baseplate further comprises signal traces located in the light-emitting region, one of the signal traces is connected to multiple of the bonding pins; and in the bonding pins connected with the one of the signal traces, second conductive structures of at least two adjacent bonding pins are connected.

15. The light-emitting baseplate according to claim 14, wherein the second conductive structures of the bonding pins connected to the one of the signal traces are all connected.

16. A display apparatus, comprising the light-emitting baseplate according to claim 1.
